(19) United States
(12) Patent Application Publication
(10) Pub. No.: US 2025/0112611 A1
(43) Pub. Date: Apr. 3, 2025

(54) DUAL-BAND IMPEDANCE MATCHING CIRCUIT AND METHOD OF IMPEDANCE MATCHING

(71) Applicants: Farzad Yazdani, Richmond Hill (CA); Raafat R. Mansour, Waterloo (CA); Huawei Technologies Canada Co., Ltd., Kanata (CA)

(72) Inventors: Farzad Yazdani, Richmond Hill (CA); Raafat R. Mansour, Waterloo (CA)

(21) Appl. No.: 18/980,529

(22) Filed: Dec. 13, 2024

Related U.S. Application Data
(63) Continuation of application No. PCT/CA2022/050948, filed on Jun. 14, 2022.

(51) Int. Cl. H03H 7/38; H01P 1/203; H03H 7/01; H03H 7/20

(52) U.S. Cl. CPC H03H 7/38; H01P 1/2039; H03H 7/20; H03H 2007/013

(57) ABSTRACT

A circuit has a source, a load, and a tuning component connected to the source and load. The source has a source impedance and for generating an input signal at a first and a second frequency. The load has a load impedance and a first input reflection coefficient and for generating an output signal at the first and second frequencies. The tuning component has a first filter having a first output reflection coefficient and for modifying a magnitude of the first output reflection coefficient based on the first input reflection coefficient, and a first phase shifter connected to the first filter and for introducing a first phase shift to the first output reflection coefficient. The tuning component simultaneously matches the source impedance to the load impedance at each of the first and second frequencies, and is tunable for adjusting the first output reflection coefficient and/or the first phase shift.

### CROSS-REFERENCE TO RELATED APPLICATION

This application is a continuation of Patent Cooperation Treaty Application Serial No. PCT/CA2022/050948, entitled “DUAL-BAND IMPEDANCE MATCHING CIRCUIT AND METHOD OF IMPEDANCE MATCHING,” filed on Jun. 14, 2022, the content of which is incorporated herein by reference in its entirety.

### FIELD

The present disclosure relates to wireless communications, and in particular to a dual-band impedance matching circuit and method of impedance matching.

### BACKGROUND

Novel communication systems, including but not limited to 5G cellular networks and software defined/cognitive radio technologies, call for compact, multi-band, and reconfigurable circuit components. Specifically, multi-band Power Amplifiers (PAs) and multiband antennas are widely employed in 5G systems. Simultaneously, these devices need to be tunable so that they can cover the numerous bands of wireless networks.

Impedance tuners are fundamental microwave components that allow maximum power transfer between different components. An increasing number of multiband components such as antennas, PAs, power dividers, and baluns, among others, are being used, and these components require multiband matching networks. As a result, the desired matching networks should be able to simultaneously address the variable frequency bands (shifts in frequency) and variable impedances of the different components. In more detail, the requirements of multiband impedance tuners include varying frequency ratios, wide impedance coverage at each frequency, low loss, and high power performance. Moreover, it is desirable for the design of the tuner for a given band to be independent from the design of a tuner for another band.

Conventional distributed designs of single and dual-band RF impedance matching circuits rely on modifying the characteristic impedance of transmission lines. This limits the achievable impedance coverage due to technology limitations. Furthermore, making such devices reconfigurable dramatically degrades their performance. Moreover, matching networks that can match loads with certain frequency ratios are limited, despite their potential for wide-ranging applications.

### SUMMARY

According to one aspect of this disclosure, there is provided a dual-band impedance matching circuit, comprising: a source having a source impedance and configured to generate an input signal at a first frequency and a second frequency; a dual-band load having a load impedance and a first input reflection coefficient, and configured to generate, based on the input signal, an output signal at the first and second frequencies; and a dual-band tuning component having an input connected to the source and an output connected to the load, and comprising: at least a first filter having a first output reflection coefficient and configured, based on the first input reflection coefficient of the load, to modify at least a magnitude of the first output reflection coefficient of the first filter, and at least a first phase shifter connected to the first filter and configured to introduce at least a first phase shift to the first output reflection coefficient of the first filter; the tuning component is configured to simultaneously match, at each of the first and second frequencies, the source impedance to the load impedance; and the tuning component is tunable so as to enable adjustment of one or more of: the first output reflection coefficient, and the first phase shift.

In some embodiments, the dual-band tuning component comprises: a first tuning element comprising: the first filter, and the first phase shifter; and a second tuning element comprising: a second filter having a second output reflection coefficient and configured, based on a second input reflection coefficient of the load, to modify at least a magnitude of the second output reflection coefficient of the second filter, and a second phase shifter connected to the second filter and configured to introduce a second phase shift to the second output reflection coefficient of the second filter.

In some embodiments, an output of the first tuning element is connected to an input of the second tuning element.

In some embodiments, the dual-band tuning component further comprises: a first manifold structure connecting the source to each of the first tuning element and the second tuning element; and a second manifold structure connecting each of the first tuning element and the second tuning element to the load; the first manifold structure is configured to allow the input signal to pass therethrough at the first frequency but not the second frequency; and the second manifold structure is configured to allow the input signal to pass therethrough at the second frequency but not the first frequency.

In some embodiments, the first frequency is lower than the second frequency; and the first filter is a band pass filter configured, at the first frequency and the second frequency, but not at frequencies below the first frequency and at frequencies above the second frequency, to modify at least the magnitude of the first output reflection coefficient of the first filter.

In some embodiments, the first phase shifter is a dual-band phase shifter configured to introduce: the first phase shift to the first output reflection coefficient of the first filter at the first frequency; and a second phase shift to the first output reflection coefficient of the first filter at the second frequency.

In some embodiments, the first frequency is lower than the second frequency; the first phase shifter is configured to introduce the first phase shift to the first output reflection coefficient of the first filter at the first frequency, the first phase shift is up to 180°; and the second phase shifter is configured to introduce the second phase shift to the second output reflection coefficient of the second filter at the second frequency, the second phase shift is up to 180°.

In some embodiments, the first frequency is lower than the second frequency; the first filter is one of: a low-pass filter configured, at the first frequency but not the second frequency, to modify at least the magnitude of the output reflection coefficient of the low-pass filter, and a high-pass filter configured, at the second frequency but not the first frequency, to modify at least the magnitude of the output reflection coefficient of the high-pass filter; and the second filter is the other of: the low-pass filter, and the high-pass filter.

In some embodiments, at least one of the first phase shifter and the second phase shifter comprises a transmission line segment.

In some embodiments, the first phase shifter is a reflection-type phase shifter comprising a 90° coupler connected to a pair of reflective loads.

In some embodiments, the first phase shifter comprises a dual-band branch-line coupler comprising a pair of T-networks or pi-networks.

In some embodiments, one or more of the first filter, the first phase shifter, the second filter, and the second phase shifter is tunable so as to enable adjustment of, respectively, one or more of the first output reflection coefficient, the first phase shift, the second output reflection coefficient, and the second phase shift.

In some embodiments, each of the first phase shifter and the second phase shifter is a reflection-type phase shifter comprising a 90° coupler connected to a reflective load; and each of the first phase shifter and the second phase shifter is tunable so as to enable adjustment of, respectively, the first phase shift and the second phase shift.

In some embodiments, the first filter is a band stop filter configured, at the first frequency and the second frequency, but not at frequencies between the first frequency and the second frequency, to modify at least the magnitude of the first output reflection coefficient of the first filter.

In some embodiments, the band stop filter comprises one or more of: one or more open-circuited stubs; and one or more slots in a ground plane of one or more microstrip lines.

In some embodiments, the tuning component comprises one or more lumped or distributed circuit components.

According to one aspect of this disclosure, there is provided a dual-band impedance matching circuit, comprising: a source having a source impedance and configured to generate an input signal at a first frequency and a second frequency; a dual-band load having a load impedance and first and second input reflection coefficients, and configured to generate, based on the input signal, an output signal at the first and second frequencies; a first tuning element comprising: a first filter having a first output reflection coefficient and configured, based on the first input reflection coefficient of the load, to modify at least a magnitude of the first output reflection coefficient of the first filter, and a first phase shifter connected to the first filter and configured to introduce a first phase shift to the first output reflection coefficient of the first filter; and a second tuning element comprising: a second filter having a second output reflection coefficient and configured, based on the second input reflection coefficient of the load, to modify at least a magnitude of the second output reflection coefficient of the second filter, and a second phase shifter connected to the second filter and configured to introduce a second phase shift to the second output reflection coefficient of the second filter; the tuning component is configured to simultaneously match, at each of the first and second frequencies, the source impedance to the load impedance; and the first frequency is lower than the second frequency, the first filter is one of: a low-pass filter configured to allow the input signal to pass therethrough at the first frequency but not the second frequency, and a high-pass filter configured to allow the input signal to pass therethrough at the second frequency but not the first frequency, and the second filter is the other of: the low-pass filter, and the high-pass filter.

According to one aspect of this disclosure, there is provided a dual-band impedance matching circuit, comprising: a source having a source impedance and configured to generate an input signal at a first frequency and a second frequency, wherein the first frequency is lower than the second frequency; a dual-band load having a load impedance and a first input reflection coefficient, and configured to generate, based on the input signal, an output signal at the first and second frequencies; and a dual-band tuning component having an input connected to the source and an output connected to the load, and comprising: a band pass filter having an output reflection coefficient and configured, at the first frequency and the second frequency, but not at frequencies below the first frequency and at frequencies above the second frequency, to modify, based on the input reflection coefficient of the load, a least a magnitude of the output reflection coefficient of the band pass filter, and a dual-band phase shifter connected to the filter and configured to introduce, at the first frequency, a first phase shift to the output reflection coefficient of the band pass filter and, at the second frequency, a second phase shift to the output reflection coefficient of the band pass filter; the tuning component is configured to simultaneously match, at each of the first and second frequencies, the source impedance to the load impedance.

According to one aspect of this disclosure, there is provided a dual-band impedance matching circuit, comprising: a source having a source impedance and configured to generate an input signal at a first frequency and a second frequency; a dual-band load having a load impedance and an input reflection coefficient, and configured to generate, based on the input signal, an output signal at the first and second frequencies; and a dual-band tuning component having an input connected to the source and an output connected to the load, and comprising: at least a first filter having a first output reflection coefficient and configured, based on the input reflection coefficient of the load, to modify at least a magnitude of the output reflection coefficient of the first filter, and at least a first phase shifter connected to the first filter and configured to introduce at least a first phase shift to the output reflection coefficient of the first filter; the tuning component is configured to simultaneously match, at each of the first and second frequencies, the source impedance to the load impedance; and the first phase shifter comprises a dual-band branch-line coupler comprising a pair of T-networks or pi-networks.

Advantages of the embodiments described herein include but are not limited to flexibility of design in terms of implementation circuit technology, compactness, the ability to address various ranges of frequency ratios, independence from high and/or low characteristic impedance of the transmission lines being used, wideband performance, ease of design, compatibility with lumped and distributed circuits, compatibility with high-power applications, compatibility with fixed and tunable load impedances, and the ability to independently match at either frequency band.

This summary does not necessarily describe the entire scope of all aspects. Other aspects, features, and advantages will be apparent to those of ordinary skill in the art upon review of the following description of specific embodiments.

### BRIEF DESCRIPTION OF THE DRAWINGS

Embodiments of the disclosure will now be described in detail in conjunction with the accompanying drawings of which:

FIG. 1 shows a circuit for performing impedance matching at a single frequency band;

FIG. 2 shows a cascade architecture for performing impedance matching at dual frequency bands, according to an embodiment of the disclosure;

FIG. 3 shows a manifold architecture for performing impedance matching at dual frequency bands, according to an embodiment of the disclosure;

FIG. 4 shows a cascade architecture for performing impedance matching at dual frequency bands, as well as the associated performance of the cascade architecture, according to an embodiment of the disclosure;

FIG. 5 shows an alternative cascade architecture for performing impedance matching at dual frequency bands, according to an embodiment of the disclosure;

FIG. 6 shows a microstrip circuit layout for a fixed dual-band impedance matching network, according to an embodiment of the disclosure;

FIG. 7 shows the performance (S-parameter as a function of frequency) of the circuit of FIG. 6, according to an embodiment of the disclosure;

FIG. 8 shows the alternative cascade architecture as part of a fixed dual-band impedance matching network, according to an embodiment of the disclosure;

FIG. 9 shows circuit layouts for the fixed dual-band impedance matching network of FIG. 8, according to an embodiment of the disclosure;

FIG. 10 shows the performance (S-parameters as a function of frequency) of the circuit of FIG. 9, according to an embodiment of the disclosure;

FIG. 11 shows circuit layouts for a fixed dual-band impedance matching network, according to an embodiment of the disclosure;

FIG. 12 shows the performance (S-parameters as a function of frequency) of the circuit of FIG. 11, according to an embodiment of the disclosure;

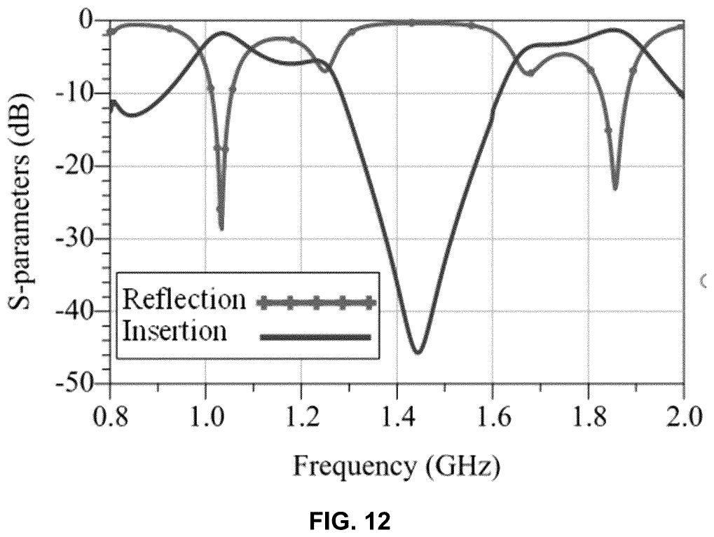

FIG. 13 shows a circuit layout for a tunable dual-band impedance matching network, according to an embodiment of the disclosure;

FIG. 14 shows a circuit layout for tunable phase shifters used in the tunable dual-band impedance matching network of FIG. 13, according to an embodiment of the disclosure;

FIG. 15 shows the performance (S-parameter as a function of frequency) of the circuit of FIG. 13, according to an embodiment of the disclosure;

FIG. 16 shows a circuit layout for a tunable dual-band impedance matching network, according to an embodiment of the disclosure;

FIG. 17 shows the impedance coverage at the higher frequency band (output reflection coefficient on the Smith Chart at two frequencies) of the circuit of FIG. 16, according to an embodiment of the disclosure;

FIG. 18 shows the performance (S-parameters as a function of frequency) of the circuit of FIG. 16, according to an embodiment of the disclosure;

FIG. 19 shows the impedance coverage at the lower frequency band (output reflection coefficient on the Smith Chart at two frequencies) of the circuit of FIG. 16, according to an embodiment of the disclosure;

FIG. 20 shows the performance (S-parameters as a function of frequency) of the circuit of FIG. 16, according to an embodiment of the disclosure;

FIG. 21 shows a circuit layout for a tunable dual-band impedance matching network, according to an embodiment of the disclosure;

FIG. 22 shows the performance (reflection coefficient as a function of frequency) of the filters of FIG. 21, according to an embodiment of the disclosure;

FIG. 23 shows the impedance coverage over the higher frequency bands (output reflection coefficient on the Smith Chart at four frequencies) of a circuit using the filters of FIG. 21, according to an embodiment of the disclosure;

FIG. 24 shows the performance (S-parameters as a function of frequency) of a circuit using the filters of FIG. 21, according to an embodiment of the disclosure;

FIG. 25 shows the impedance coverage over the lower frequency bands (output reflection coefficient on the Smith Chart at four frequencies) of a circuit using the filters of FIG. 21, according to an embodiment of the disclosure; and

FIG. 26 shows the performance (S-parameters as a function of frequency) of a circuit using the filters of FIG. 21, according to an embodiment of the disclosure.

### DETAILED DESCRIPTION

The present disclosure seeks to provide an improved dual-band impedance matching circuit design and implementation methodology that may provide matching for dual-band loads that are fixed and/or tunable in terms of load impedances and at two frequencies of operation. While various embodiments of the disclosure are described below, the disclosure is not limited to these embodiments, and variations of these embodiments may well fall within the scope of the disclosure which is to be limited only by the appended claims.

Embodiments of the disclosure may resolve the problem of limited coverage at multiple bands by employing, in a cascade architecture, a combination of microwave filters and phase shifters such that, at each band, the output reflection coefficient of the filter and the phase shift of the phase shifter compensate the magnitude and phase of the load to be matched, respectively. The filters and phase shifters may be embodied using circuit elements, which may avoid high or low characteristic impedances. Circuit architectures for this concept, as well as the requirements for the filters and phase shifters, are presented. Embodiments are then described for the impedance matching of constant loads Embodiments for variable loads with different frequency ratios are also presented.

According to embodiments of the disclosure, the range of impedances that may be matched is independent of the characteristic impedance of the transmission lines used in the circuitry. Furthermore, embodiments of the disclosure may perform impedance matching for a range of frequency ratios (the ratio of the higher frequency band to the lower frequency band), thereby enabling impedance-matching for loads with variable impedance and frequency ratios. Further still, embodiments of the disclosure may enable impedance matching at either band independently of the other band.

According to embodiments of the disclosure, circuits are disclosed for dual-band impedance matching networks for variable dual-band loads. Embodiments of the disclosure use filters and phase shifters to improve the impedance matching between a 50Ω source and a dual-band load, at both bands. Several embodiments are disclosed using high-pass filters, low-pass filters, band-pass filters, and band-stop filters, as well as single-band and dual-band phase shifters.

The circuits are suitable for both constant and tunable dual-band load impedances.

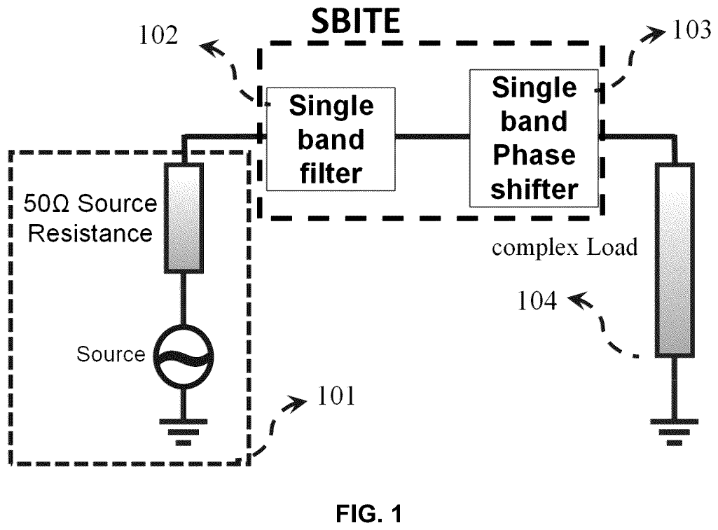

According to a first embodiment of the disclosure, with reference to FIG. 1, there is shown a circuit comprising at least two sub-components that may be referred to as Single-band Impedance Tuning Elements (SBITEs). Each SBITE comprises a single-band microwave filter 102 and a single-band phase shifter 103. The mechanism of each SBITE can be explained by terminating the SBITE in a 50Ω source 101 and a load 104 with a complex impedance. Source 101 and load 104 are connected to each other by a cascade connection of filter 102 and phase shifter 103. The magnitude of the output Reflection Coefficient (RC) of the filter 102 is set to be equal to the magnitude of the RC of load 104, by tuning the cutoff frequency of filter 102. Consequently, the phase difference between the two RCs is compensated by phase shifter 103, which leads to complex conjugate matching between source 101 and load 104.

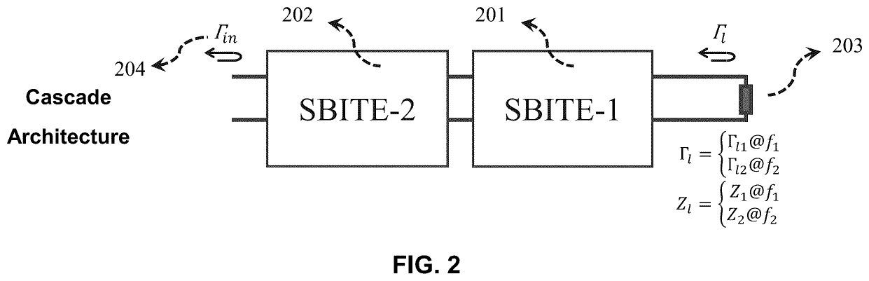

The dual-band impedance matching networks described herein employ SBITEs in a cascade or manifold configuration to achieve complex conjugate matching at two frequency bands. The cascade architecture for dual-band impedance matching is shown in FIG. 2 and comprises a first SBITE 201 and a second SBITE 202. Each of SBITE 201 and 202 provides matching at one of two frequency bands for a dual-band load impedance 203, while passing the input signal at the other frequency band. Dual-band load impedance 203 is defined by its known RCs of Γₗ₁ and Γₗ₂ or input impedances Z₁ and Z₂ at the lower frequency of f₁ and higher frequency of f₂, respectively.

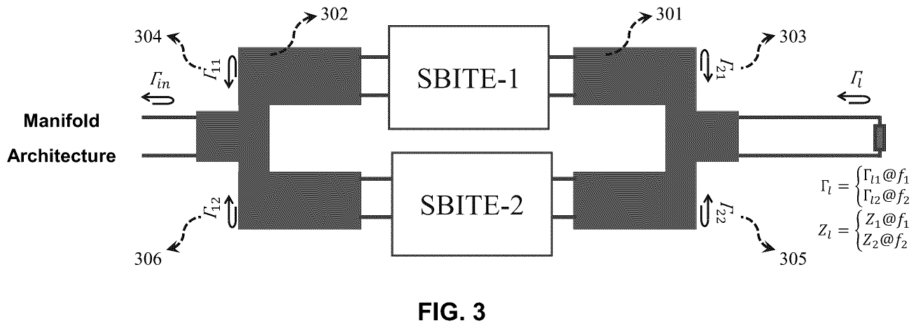

The manifold architecture for a dual-band impedance matching network is shown in FIG. 3. The manifold architecture comprises a first SBITE-1 and a second SBITE-2 which are connected to the input and output using two manifold structures 302 and 301, respectively. The input and output reflection coefficients of the top branch, 304 and 303 respectively, resemble an open circuit termination at a first frequency, while passing the signal to SBITE-1 at a second frequency. Similarly, the input and output reflection coefficients of the bottom branch, 306 and 305 respectively, pass the signal to SBITE-2 at the second frequency, while resembling an open circuit termination at the first frequency. Each SBITE, when matched at one frequency, should behave similarly to an open circuit termination at the other frequency.

The cascade architecture (FIG. 2) requires fewer components than the manifold architecture. Therefore, because of its smaller size, it may be preferred. According to some embodiments, when using the cascade architecture, the filters should have minimal impact on each other's matching capability. Although the added phase shifts are inevitable, the magnitude of the S-parameters should be addressed. To this end, according to some embodiments, the passband of each filter covers the frequency range around the response of the other filter intended for providing matching. According to some embodiments, for a dual-band application, the pass band of each filter covers either one of the two matching frequencies.

According to some embodiments, in the cascade architecture, the phase-shifters provide a maximum of 180° of phase shift at their respective frequencies. According to some embodiments, the phase-shifters have wide enough band-widths to cover both frequencies. Such bandwidths are the frequency range over which the phase shifter passes therethrough the input signal.

According to some embodiments, in the cascade architecture, the filters and phase shifters are low-loss. This may translate into low-order filters and phase shifters with low unwrapped phase.

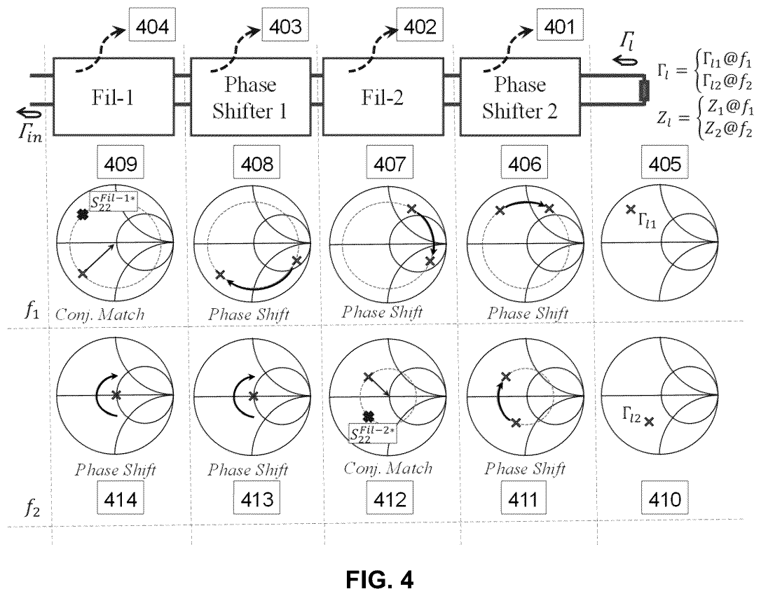

FIG. 4 describes the behavior of the cascade architecture at the two frequencies, by showing the input RC after each block looking toward the load. From load to source, the device comprises a phase shifter 401, a filter 402, a phase shifter 403, and a filter 404. For the purposes of demonstration, the components may be assumed to be lossless. Filter 402 has a passband edge near f₂ and its passband covers a vicinity of f₁. Similarly, filter 404 has a passband edge near f₁ and its passband covers a vicinity of f₂. The load impedance has an RC of Γₗ₁ at f₁. Since filter 402 has a passband at this frequency, its input RC has the same magnitude as its terminating impedance. However, its input RC has a higher phase than its termination. Consequently, the input RC 406 of phase shifter 401 and the input RC 407 of filter 402 have the same magnitude as Γₗ₁ but are rotated over the constant RC circle on the Smith chart. Moreover, the output RC of filter 404 is set to have the same magnitude as Γₗ₁. Therefore, by varying phase shifter 408, complex conjugate matching between the output RC of filter 404 and the input RC of phase shifter 1 403 is achieved 409. Similarly, the output RC of filter 402 is set according to the magnitude of the RC of the load at f₂ 410. Therefore, by setting the phase shift of phase shifter 411, complex conjugate matching between the output RC of filter 2 402 and the input RC of phase shifter 2 401 is achieved 412. Since f₂ is located over the passband of filter 404, then phase shifter 403 and filter 404 would not impact the impedance matching achieved 413 and 414. Correspondingly, the impedance matching conditions at f₁ and f₂ are expressed through equation 1 and equation 2, respectively:

$$\vert {S}_{22}^{Fil - 1} ( {f}_{1} ) \vert ∠ ( 2 ∠ {S}_{21}^{Fil - 2} ( {f}_{1} ) + 2 {φ}_{2} ( {f}_{1} ) + ∠ {S}_{22}^{Fil - 2} ( {f}_{1} ) + 2 {φ}_{1} ( {f}_{1} ) ) = {Γ}_{l 1}^{*} \qquad Equation 1$$

$$\vert {S}_{22}^{Fil - 2} ( {f}_{2} ) \vert ∠ ( ∠ {S}_{22}^{Fil - 1} ( {f}_{2} ) + 2 {φ}_{2} ( {f}_{2} ) ) = {Γ}_{l 2}^{*} \qquad Equation 2$$

φ₁ and φ₂ represent the phase shift of phase shifters 403 and 401, respectively. In these equations, the phases of the phase shifters 403 and 401 and the phases of the filters 404 and 402 over their passbands are multiplied by 2 because the signals travel twice in the incident and reflection directions. The locations of filter 404 and filter 402 in this architecture is interchangeable, and their locations can be swapped without significant change in the methodology. In this case, equations 1 and 2 may be updated accordingly.

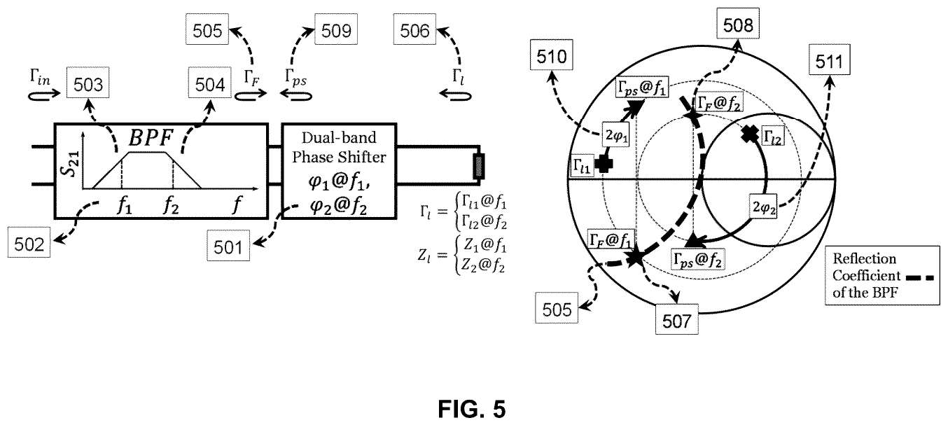

An alternative design for the cascade architecture is also disclosed with reference to FIG. 5. This design takes advantage of dual-band phase shifters. In FIG. 5, dual-band phase shifter 501 simultaneously delivers two phase shifts at two different frequencies. A Band Pass Filter (BPF) 502 is employed, and has its lower cutoff frequency 503 and higher cutoff frequency 504 near the lower and higher matching frequencies, respectively. The output RC 505 of BPF 502 is set to have the same magnitude as the RC 506 of the load at the two bands.

This is shown on a Smith chart for an arbitrary load. The center frequency and bandwidth of BPF 502 are modified so that the RC of BPF 502 intersects with a constant RC circle with the same radius as the magnitude of Γₗ₁ and Γₗ₂ at f₁ 507 and f₂ 508, respectively. Consequently, complex conjugate matching between the output RC of BPF 502 and the input RC of phase shifter 509 is achieved by fine tuning the phase shift 510 at f₁ and the phase shift 511 at f₂. Alternatively, this can be expressed as the following impedance matching conditions:

$$\vert {S}_{22}^{BPF} ( f 1 ) \vert ∠ ( ∠ {S}_{22}^{BPF} ( f 1 ) + 2 {φ}_{1} ) = {Γ}_{l 1}^{*} \qquad Equation 3$$

$$\vert {S}_{22}^{BPF} ( f 2 ) \vert ∠ ( ∠ {S}_{22}^{B P F} ( f 2 ) + 2 {ϕ}_{2} ) = {Γ}_{l 2}^{*} . \qquad Equation 4$$

Alternative filters can also be used. For example, two band pass filters, two band stop filters, or a high-pass filter and a low-pass filter may be used. This alternative design for the cascade architecture employs a fewer number of elements, and may therefore lead to a smaller footprint and lower losses. Accordingly, if the ratio of f₂/f₁ (with f₂ being the higher frequency) is large enough for the dual-band phase shifter, then this architecture may be preferred.

There will now be described various embodiments of dual-band impedance matching circuits, employing the various architectures described above. The first embodiment is based on the cascade architecture for a fixed load. The second and third embodiments are based on the alternative cascade architecture but use different phase shifters, for a fixed load. The fourth embodiment employs two tunable band pass filters in a cascade architecture, for a variable load and for relatively small frequency ratios of f₂/f₁, such as about as small as, for example, 1.06. The fourth embodiment represents a case where the frequency ratio is significantly smaller than an octave and approaches the value of unity (or the extreme case where two frequencies reach one another). The fifth embodiment employs a band stop filter in a cascade architecture, for a variable load and for moderate frequency ratios of, for example, greater than 1.2 and up to 2.2 (or greater than one octave).

### First Embodiment

There is described a fixed dual-band impedance matching network employing a high-pass filter, a low-pass filter, and two transmission line segments as phase shifters. The high-pass has a cutoff frequency near the lower matching band and its passband covers the higher matching band. Conversely, the low-pass filter has its cutoff frequency near the higher matching band and its passband covers the lower matching band. To implement the phase shifters, straight 500 transmission line segments were used. The required phase shift is obtained by varying the length of the transmission line segments. The process of designing the circuit was as follows:
1. Design the high-pass filter such that its output RC has the same magnitude as the load at f₁ and such that its passband covers f₂ with minimal ripple in insertion loss.
2. Design the low-pass filter such that its output RC has the same magnitude as the load at f₂ and such that its passband covers f₁ with minimal ripple in insertion loss.
3. Determine whether swapping the locations of the low-pass filter and the high-pass filter would result in shorter phase shifters. This was done by comparing the phase of the output RCs of the filters with the phase of the load at the two frequencies. The combination, which required smaller phase shifters, may be chosen for the purposes of miniaturization.
4. Determine the length of the transmission line phase shifters. Note that the electrical length of the transmission line segments should be half of the required phase shift at the two frequencies.
5. Develop and fine-tune an electromagnetic model of the cascade architecture. This optimization step may be required because of the non-ideal behavior of the components, as well as the coupling between them.

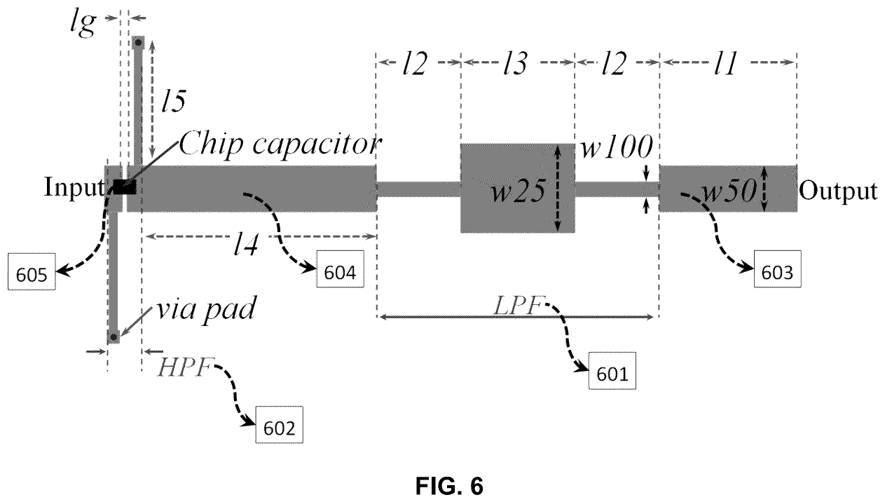

FIG. 6 shows a microstrip circuit layout for the first embodiment. This circuit serves as an illustrative example and the order of the filters can be changed, depending on the application. Furthermore, different filter types can be employed, including but not limited to Chebyshev, Butterwurth, and Quasi-elliptic filters. Moreover, the filters can be implemented using alternative methods such as using lumped inductors and capacitors if the frequency of operation allows. For simplicity, only 50Ω, 25Ω, and 100Ω transmission line segments are used. The low-pass filter 601 is a third-order stepped impedance microstrip filter, while the high-pass filter 602 employs two ground-terminated shunt stubs and a series lumped capacitor 605. The output is connected to low-pass filter 601 using a first phase shifter 603, and low-pass filter 601 and high-pass filter 602 are connected using a second phase shifter 604. The parametric dimensions of the individual parts are shown in FIG. 6.

A prototype of the first embodiment was designed for a dual-band load impedance 150+j100 and 100+j80 at 1 GHz and 1.8 GHZ, corresponding to Γₗ₁=0.635/18.43° and Γₗ₂=0.555429.9°, respectively. The frequency ratio is f₂/f₁ and is equal to 1.8. For simplicity, the value of the load impedance is assumed to be 150+j100 below 1.4 GHz. Beyond 1.4 GHz, the value of the load impedance is equal to 100+j80. The material used for the circuit board was FR-4: TG170 substrate (ϵᵣ=4.4, tan δ=0.02, thickness of 1.6 mm, and 1 oz. copper cladding). Low-pass filter 601 is a third-order Butterworth filter, while high-pass filter 602 is a third order-Chebyshev filter with 0.05 dB ripple. The dimensions of the prototype are presented in Table 1.

TABLE 1
PCB Board Dimensions (mm)

| Board size | 95 mm × 25 mm | I1 | 18 |
|---|---|---|---|
| w50 | 3.04 | I2 | 7.9 |
| w25 | 8.34 | I3 | 9.6 |
| w100 | 0.675 | I4 | 49 |
| lg | 0.3 | I5 | 7.5 |

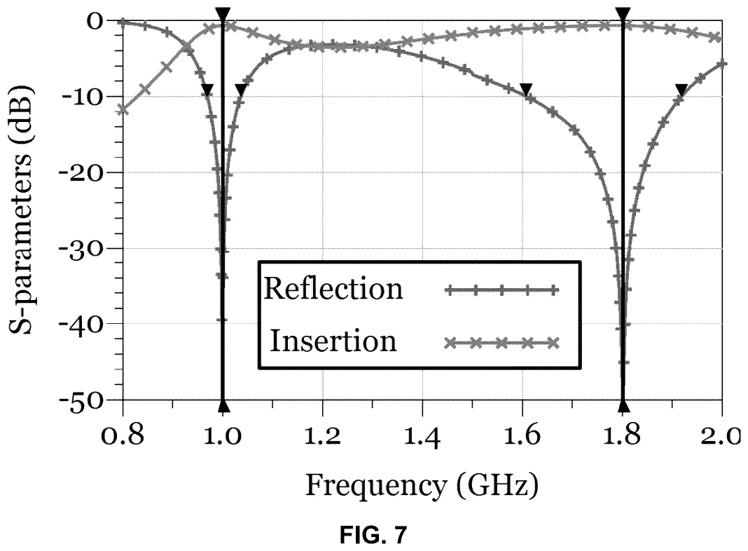

The results are shown in FIG. 7. The bandwidths for the lower and the higher frequency bands are 7% and 17.5%. The results can potentially be improved by choosing different filters, phase shifters, and low-loss substrates.

This embodiment achieves dual-band matching using transmission line segments with a set of predefined characteristic impedances. Therefore, the implementation of this design to any other loads will not require extremely high or low impedance lines. This is an improvement in terms of coverage with respect to the prior art. For example, this may resolve the problem associated with fabrication limitations. Furthermore, the embodiment may be used to embody low-loss dual-band matching networks for high-power and handheld applications. Other advantages of this embodiment may include wideband performance, ease of design, compatibility with lumped and distributed circuits, and compatibility with different fabrication technologies.

The first embodiment may be implemented using alternative circuit designs. For example, the filters may be replaced with any other kind of filter, as long as the filters have minimal impact on matching capability of each other filter used in the design. Furthermore, the order of the circuit blocks can be changed. Moreover, the phase shifters may be implemented in alternative ways, including but not limited to using transmission lines with characteristic impedances other than 500, lumped or distributed capacitor/inductor phase shifters, commensurate phase shifters, reflection type phase shifters (RTPSs), delay-lines, and any structure that induces a phase shift or time delay. Finally, individual blocks in the circuit diagram can be combined to form an intermediary architecture between the cascade architecture and its alternative architecture (as described above). This may include, but is not limited to, combining two filters into a band-pass filter, using multiband filters, using band stop filters, and using multiband phase shifters.

### Second Embodiment

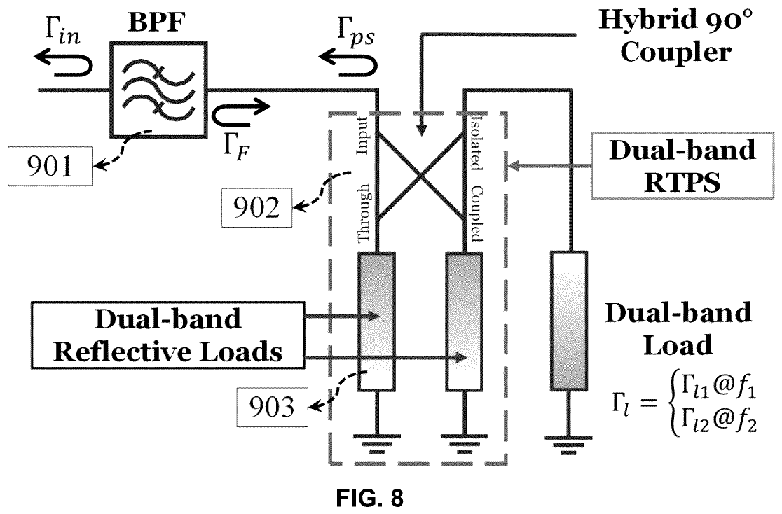

The second embodiment uses the alternative cascade architecture. A schematic of the second embodiment is presented in FIG. 8. A band-pass filter 901 and a dual-band RTPS 902 are used. RTPS comprises a hybrid 90° coupler 902 in which the through and coupled ports are terminated in a set of identical dual-band reflective loads 903. The input port of the coupler is connected to the output of band-pass filter 901, and its isolated port is connected to the dual-band load to be matched.

Band-pass filter 901 may be implemented using any know band-pass filter including tapped resonator filters, comprising resonators made from a pair of shunt open- and short-circuit terminated stubs. Depending on the order of band-pass filter 901, these resonators can be coupled by transmission line inverters and their passbands bandwidths can exceed 70%.

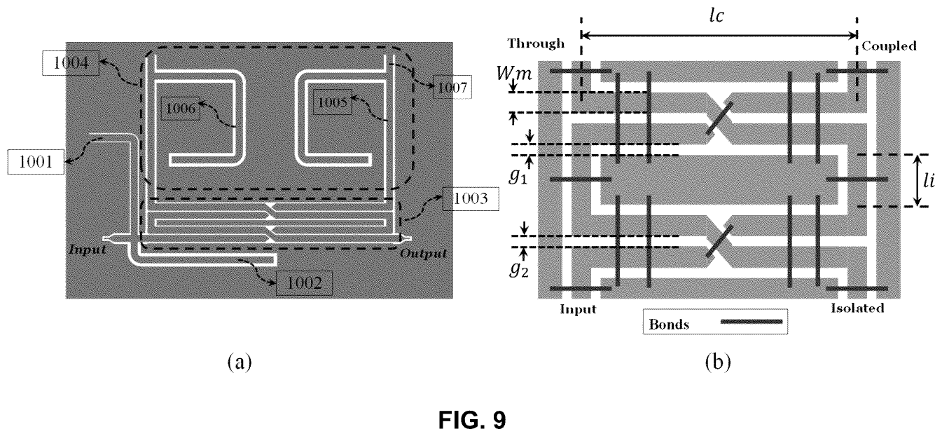

FIG. 9(a) illustrates an implementation of the second embodiment using coplanar waveguide circuitry. In this implementation, a short-circuited stub 1001 and an open-circuited stub 1002 together form band-pass 901. The implementation further includes a tandem coupler 1003 a pair of identical reflective loads 1004, each comprising a series transmission line segment 1005, a shunt open circuited stub 1006, which is folded for size reduction, and a short circuited stub 1007. For simplicity, the width of all traces are set to have the same value, Wm. Therefore, the filter response is manipulated by changing the length and gap of the short-circuited stub 1001, lsc and gsc, respectively, and the length and gap of the open circuited stub 1002, loc and goc, respectively.

Tandem hybrid coupler 1003 is illustrated in FIG. 9(b). Coupler 1003 comprises two −8.3 dB couplers which are connected in a tandem configuration to form the −3 dB coupler 1003. This may be achieved using, for example but not limited to, four coupled line segments connected by crossovers, where each segment is 45° at the center frequency. The trace widths and the coupling gaps for tandem couplers are not as narrow as other couplers (e.g. Lange couplers), and they have a wideband performance. The tandem coupler enables-3 dB coupling at f₁ and f₂. This is achieved by decreasing the gap width between the traces, g1, increasing the gap between traces and the ground plane, g2, and fine-tuning the horizontal and vertical lengths of the coupler, namely lc and li, respectively. Dual-band reflective load 1004 has a T-junction which connects folded stub 1006 and

short-circuited stub 1007 to the transmission line segment 1005. Folded stub 1006 has a 90° electrical length at f₂, which creates a short-circuit termination. As a result, the length of short-circuited stub 1007 does not influence the electrical length of the reflective load at f₂. This allows reflective load 1003 to have independent reflection coefficients at the two frequencies. Alternatively, folded stub 1006 can be implemented using radial stubs.

A prototype of the second embodiment was designed for the same dual-band load used in the first embodiment. The prototype was designed using coplanar waveguide segments on Alumina substrate with ϵᵣ=9.9, tan δ=0.0001, a substrate thickness of 10 mils, and in which the circuit was electroplated over the substrate using 4 μm of gold. The circuit dimensions are listed in Table 2.

TABLE 2

| | VARIABLE | | Values μm |
|---|---|---|---|
| | Wm | | 700 |
| BPF | gsc | | 100 |
| | goc | | 300 |
| | loc | | 15503 |
| | lsc | | 14130 |
| Dual-band | Shunt O.C. | Gap | 300 |
| Reflective | stub | Length | 23306 |
| Loads | Serries TL | Gap | 188 |
| | segment | Length | 12207 |
| | Shunt O.C. | Gap | 188 |
| | stub | Length | 1732 |

| | |
|---|---|
| Tandem | g1 = 129, g2 = 120, lc = |
| Coupler | 23500, li = 500 |

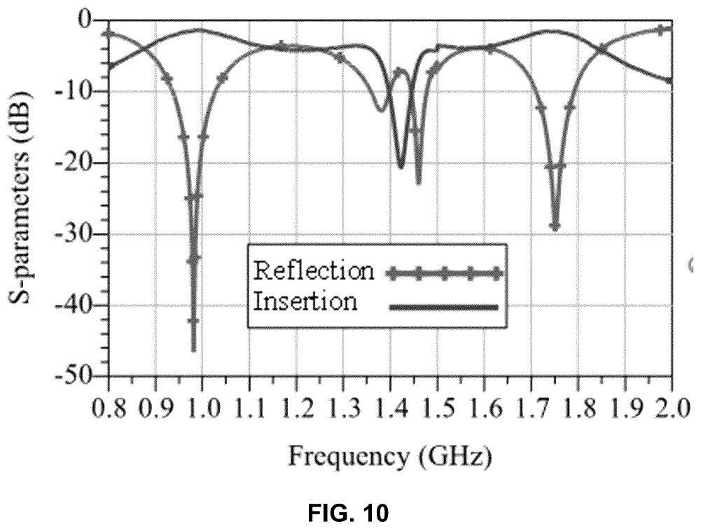

FIG. 10 shows the measured S-parameters for the prototype of the second embodiment. The matched bandwidths are 9% and 5% for the lower and higher bands, respectively. The insertion losses are 1.47 dB and 1.58 dB at the center frequencies of the lower and higher bands, respectively.

Various modifications may be made to the second embodiment. For example, the tandem coupler 1003 may be replaced with an alternative 90° hybrid coupler design including but not limited to coupled line hybrid couplers, branch-line couplers, lumped and/or distributed lattice hybrid couplers, and balanced or unbalanced couplers. Moreover, the reflective loads may be implemented using lumped circuit elements, as well as alternative stub configurations such as but not limited to radial stubs. Further still, the second embodiment may be implemented using other alternative technologies including but not limited to microstrip circuits, stripline circuits, as well as three-dimensional transmission line structures such as rectangular waveguides and coaxial waveguides.

In addition to the advantages of the first embodiment, the second embodiment may enjoy significant size reduction and low-loss performance through the combination of circuit components.

### Third Embodiment

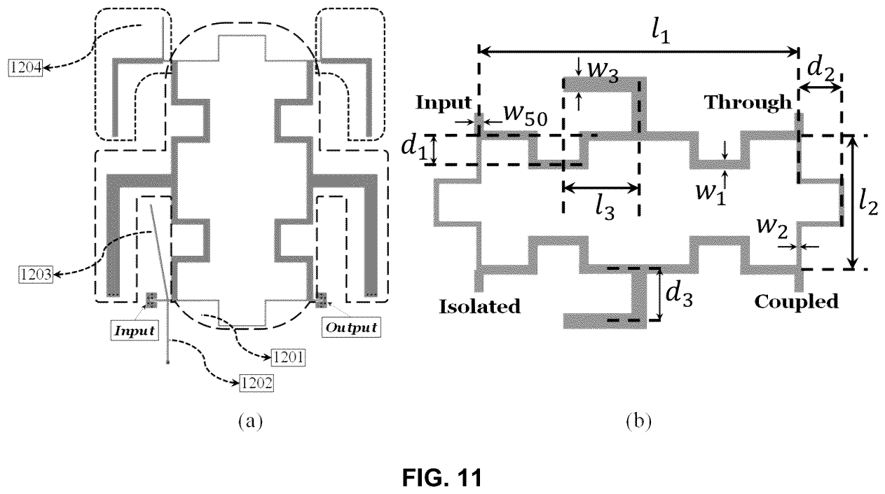

An alternative version of the second embodiment is achievable using dual-band branch-line couplers. These hybrid couplers may be implemented by replacing the branches of the conventional branch-line couplers with T-networks for frequency ratios greater than 1.5, or TT-networks otherwise. FIG. 11(a) shows one implementation of the third embodiment in which a T-network using microstrip lines is used. The circuit comprises a dual-band branch-line coupler using T-networks 1201, a short-circuited stub 1202, open-circuited stub 1203, and a pair of dual-band reflective loads 1204. The parametric dimensions of hybrid coupler 1201 are presented in FIG. 11(b). Hybrid coupler 1201 and its T-network are meandered for size reduction. Moreover, open-circuited stub 1203 of band-pass filter 502 is rotated by 10° to suppress coupling with hybrid coupler 1201.

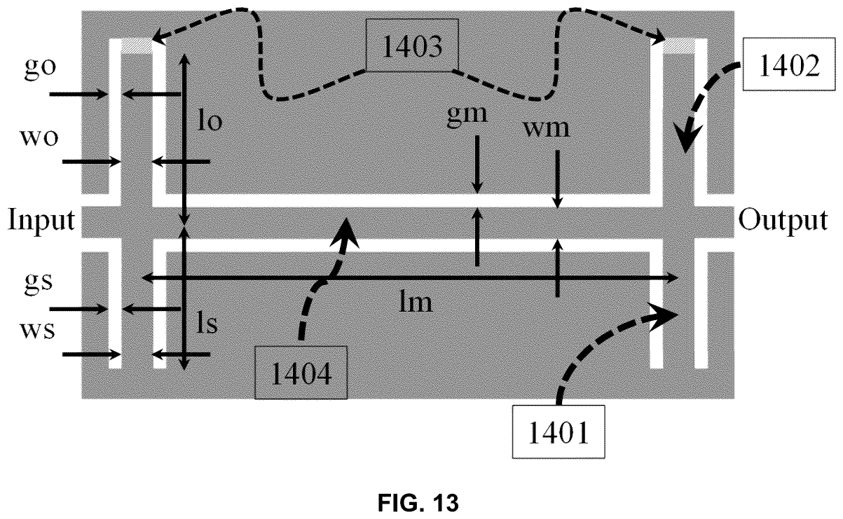

A prototype of the third embodiment was designed for the same dual-band load used in the previous embodiments. The prototype circuit was based on the same substrate used for the second embodiment. The dimensions of the fabricated prototype are listed in Table 3. FIG. 13 shows the fabricated prototype as well as the measurement results. The bandwidths are 4% and 3% for the lower and higher bands, respectively. The insertion losses are 1.76 dB and 1.32 dB at the center frequencies of the lower and higher bands, respectively. These results are negatively impacted by fabrication error such as some vias not being covered by gold.

TABLE 3

| | VARIABLE | | Values μm |
|---|---|---|---|
| | Wm | | 239 |
| BPF | loc | | 11430 |
| | lsc | | 7121 |
| Dual-band | Shunt O.C. | Width | 714 |
| Reflective | stub | Length | 14662 |
| Loads | Serries TL | Width | 239 |
| | segment | Length | 924 |
| | Shunt O.C. | Width | 239 |
| | stub | Length | 5080 |

| | |
|---|---|
| T-network | w₅₀ = 239, w₁ = 802, w₂ = 190, w₃ = 1603, |
| Coupler | d₁ = 3802, d₂ = 3000, d₃ = 6797, |
| | l₁ = 28364, l₂ = 15960, l₃ = 1382 |

Alternatives to the third embodiment include employing any of the above-described modifications to the first and second embodiments, employing any other known type of dual-band phase shifter, and employing TT-networks instead of T-networks. In addition to the advantages discussed above in connection with the first and second embodiments, the third embodiment has the advantage of truly monolithic embodiment. For example, in the third embodiment, there may be no need for wire bonding and air bridges. This, in addition its bent components, may suggest it as a suitable candidate for integrated circuits.

### Fourth Embodiment

The fourth embodiment relates to a tunable dual-band reconfigurable impedance matching network employing tunable band-pass filters and tunable phase shifters in a cascade architecture. This embodiment may be suitable for relatively small frequency ratios (f₂/f₁). The embodiment may be used for achieving coverage at 3.4 GHz and 3.7 GHZ with a frequency ratio of f₂/f₁=1.09. Generally, any combination of filters, including but not limited to a high-pass filter and a low-pass filter may be used. In a particular implementation, band-pass filters were chosen because the cut-off and center frequencies could be consistently tuned using a tapped resonator filters. In this particular implementation, a variable capacitor with a capacitance ratio of less than 5 was used. This was achieved using different available tuning elements including, but not limited to, Barium Strontium Titanate (BST) variable capacitors, semiconductor varactors, and micro-electromechanical switched and continuously tunable capacitors. This embodiment can be tuned continuously, but can be modified to use RF switches for high-frequency and/or low-loss applications. The embodiment is designed for planar circuits, but may be implemented using three-dimension structures and transmission lines.

The fourth embodiment uses the block diagram shown in FIG. 4, where filter 404 and filter 402 are implemented using tunable band-pass filters, and phase shifters 403 and 404 are implemented using single-band tunable phase shifters.

According to one implementation, the band-pass filters may comprise second-order tapped transmission line filter topologies. These filters can achieve a wideband performance of up to 72% bandwidth. The second-order filters were used to achieve low-loss, narrow bandwidths, and a sharp reflection coefficient roll-off rate for a small frequency ratio. A layout of the band-pass filters using coplanar waveguide lines is illustrated in FIG. 13. The filters comprise two resonators that are connected to each other using a transmission line inverter 1404. Each resonator comprises a short-circuited 1401 stub and an open-circuited 1402 stub in parallel. The open-ended segments for the two resonators are terminated by identical tunable capacitors 1403. The filters are designed such that their response shifts in frequency when the values of the capacitors are tuned. Accordingly, filter 404 has its passband over f₂ for a range of tuning values of the capacitor, while its lower response edge covers a range of output reflection coefficients at f₁. Similarly, filter 402 has its passband over f₁ for a range of capacitor values, while its higher response edge covers a range of output reflection coefficients at f₂. Any of f₁ and f₂ may be fixed or variable, depending on the scenario.

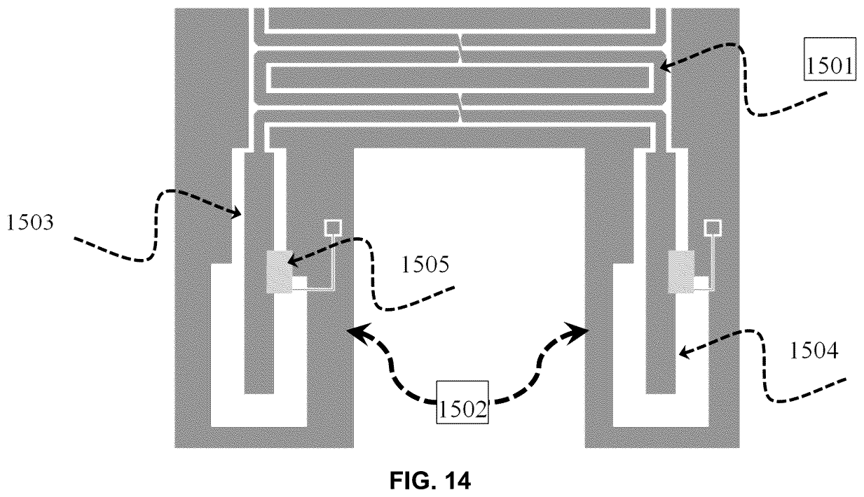

FIG. 14 shows a potential implementation of a tunable phase shifter. The phase shifters are single-band reflection-type phase shifters comprising a wideband tandem hybrid coupler 1501 and two single tuning element loaded line reflective loads 1502. These components may be replaced with alternative components. For example, the hybrid coupler can be replaced by coupled line couplers, branch-line couplers, or lumped lattice network couplers. Moreover, reflective loads 1502 may be replaced with loaded lines with more tuning elements, or switched length transmission line segments. Furthermore, employing such alternative loaded designs may result in multiband operation of the phase shifter.

Each reflective load 1502 comprises a series transmission line segment 1503 and an open or short-circuit terminated stub 1504. These two segments are separated by a tunable capacitor 1505, which is connected to the junction on one side and to the ground on the other side. Capacitor 1505 can be separated from the junction by an extension transmission line segment. The phase shift, the number of bands, and the bandwidth of the phase shifter can be increased by extending the reflective load and increasing the number of stubs and tuning capacitors.

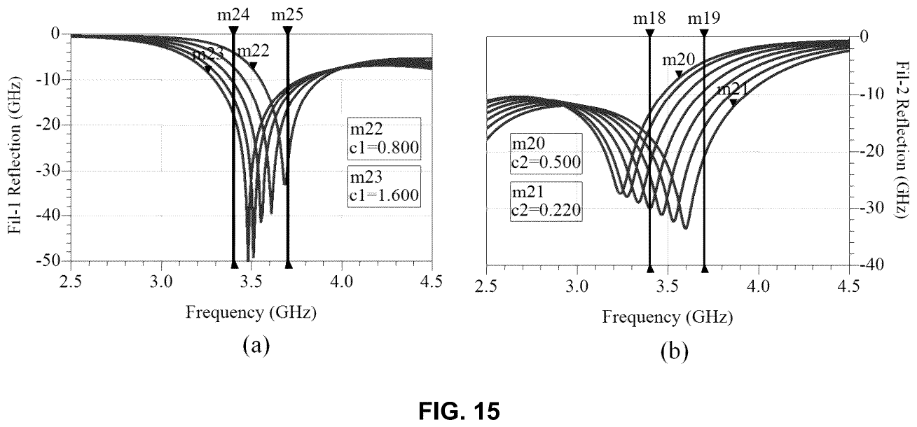

A prototype of the fourth embodiment was developed using coplanar waveguide lines on the same Alumina substrate used for the third embodiment. The prototype was designed for two frequency bands of 3.4 GHz and 3.7 GHz. The dimensions for filter 404 and filter 402 are listed in Table. 4. FIG. 15(a) shows the response of filter 404 when the capacitors are tuned from 0.8 pF to 1.6 pF. The output RC at 3.4 GHz covers the values up to −4 dB, while remaining better than −11 dB at 3.7 GHZ. Note that the higher matched band can be tuned over the frequency range between 3.6 GHz and 3.8 GHZ. FIG. 15(b) shows the response of filter 402 when the capacitors are tuned from 0.22 pF to 0.5 pF. The output RC at 3.7 GHz covers the values up to −4 dB, while remaining below than −13 dB at 3.4 GHz. Note that the lower matched band can be tuned over the frequency range below 3.45 GHz. As a result, for this particular embodiment, frequency ratios as small as 1.06 can be matched. This range of frequency ratios can be changed depending on the order and type of the filters and phase shifters.

TABLE 4

| | Fil-1 | Fil-2 |
|---|---|---|
| Design | Dimensions | Dimensions |
| variables | (mm) | (mm) |
| lm | 11.55 | 7.62 |
| lo | 7.94 | 2.85 |
| ls | 8.00 | 9.64 |
| wm | 0.38 | 0.49 |
| wo | 0.35 | 0.46 |
| ws | 0.31 | 0.48 |
| gm | 0.16 | 0.13 |
| go | 0.3 | 0.17 |
| gs | 0.28 | 0.12 |

The tandem couplers 1501 comprise four couples of line couplers. The trace widths of the coupled line couplers are 293 μm. The traces are separated from each other and the ground plane by 103 μm and 100 μm, respectively. The two top couplers, similarly to the two bottom couplers, are connected in the middle using a crossover. The crossovers are formed by connecting the top and bottom traces of the neighboring couplers using a diagonal trace and air bridges. According to this particular implementation, the top and bottom couplers are connected to each other using coplanar transmission lines with a width of 293 μm, a gap of 115 μm, and a length of 700 μm. The series stubs 1503 comprise coplanar transmission lines with a width of 700 μm, a gap of 281 μm, and a length of 2.62 mm. The open-circuited stubs 1504 have a width of 293 μm, a gap of 765 μm, and a length of 3.05 mm. Consequently, a pair of tunable capacitors 1505 with a range of 0.45 pF to 2.2 pF may provide a phase shift of at least 180° from 3 GHz to 4 GHz.

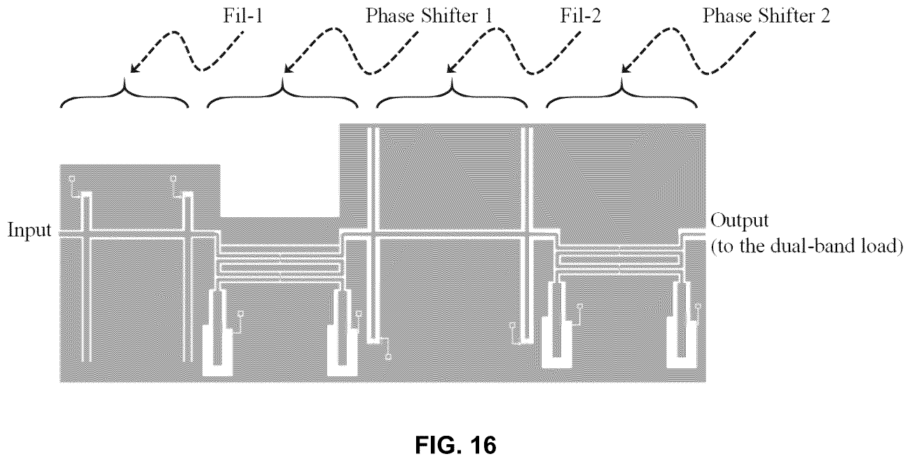

FIG. 16 shows a layout of a particular implementation of the fourth embodiment. The overall area of the layout is 5 cm by 2 cm. The fourth embodiment may be significantly miniaturized since all the transmission line segments can be bent or meandered. The locations of the bias pads are highlighted. The circuit includes eight tuning elements that are biased in pairs using four bias voltages.

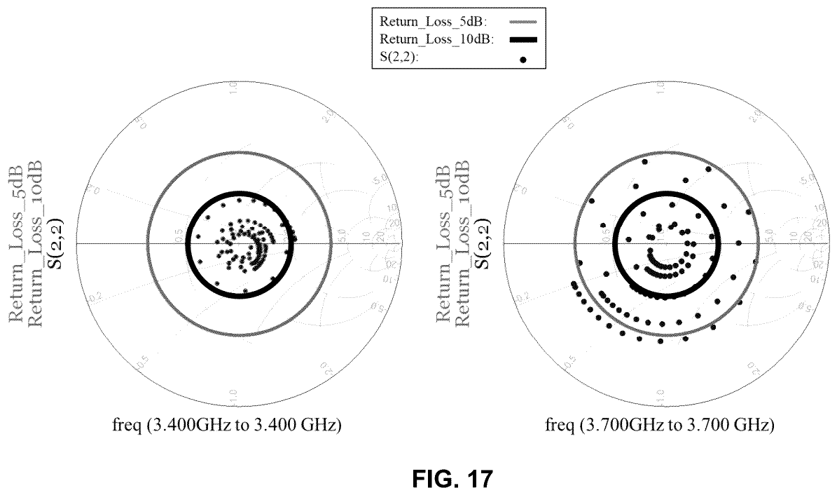

FIG. 17 shows the coverage when the tuning capacitors of filter 404 and phase shifter 403 are kept at 1.5 pF and 0.9 pF, respectively, and the values of the capacitors for filter 402 and phase shifter 401 are swept. As can be seen, the output reflection coefficient at 3.4 GHz remains better than 10 dB, while the reflection coefficients inside the −5 dB circle are covered at 3.7 GHZ.

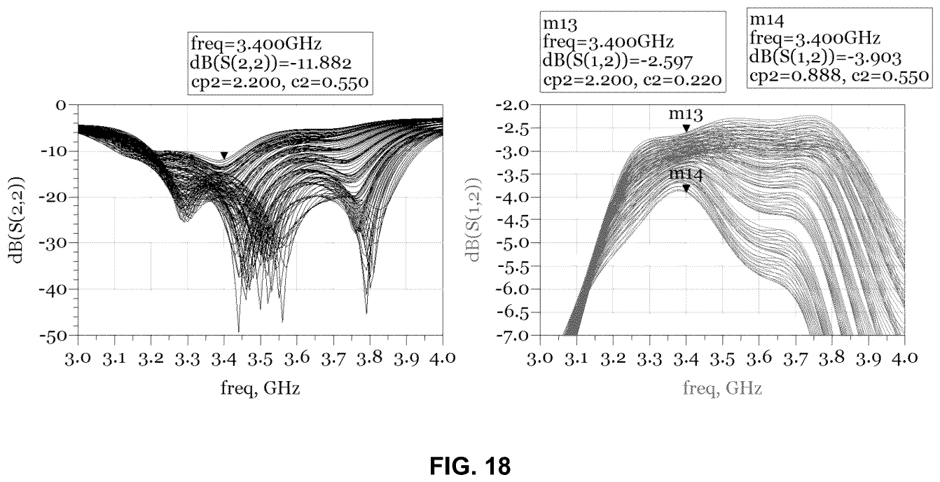

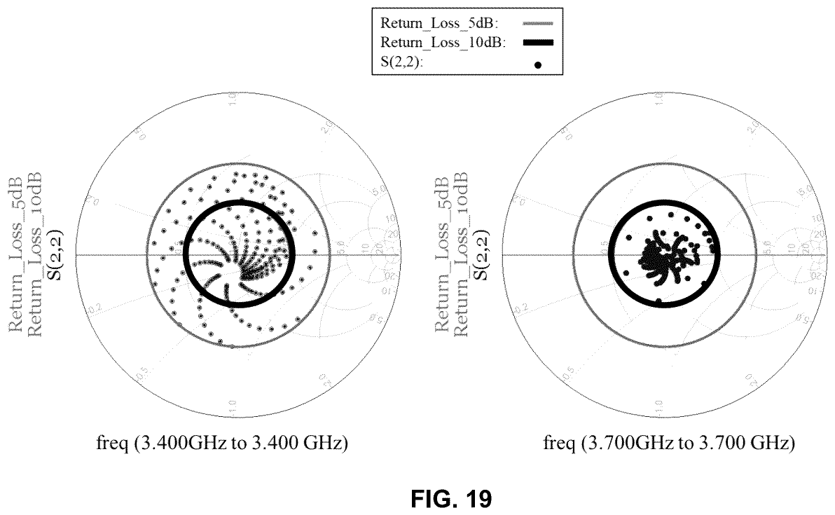

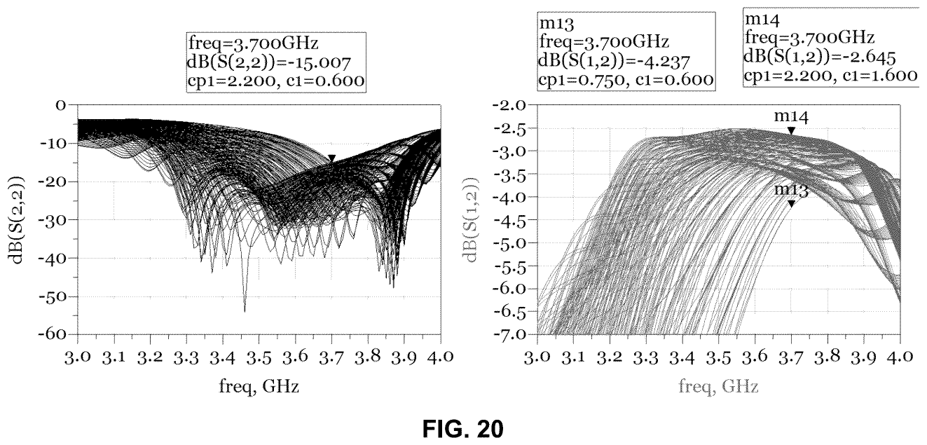

FIG. 18 shows the output return loss and the insertion loss for the same variations in capacitor values as described above. The return loss remains better than 12 dB and the insertion loss variation is roughly 1.3 dB. In addition, FIG. 19 shows the coverage when the capacitors of filter 402 and phase shifter 401 are set to 0.2 pF and 0.6 pF, respectively. Consistent coverage for the impedances inside the 5 dB circle at 3.4 GHz is shown in this figure as well. FIG. 20 shows the output return loss and the insertion loss for the same variations in capacitor values as described above. Here, the output return loss remains better than 15 dB and the insertion loss variation is roughly 1.6 dB. For cases where the two frequencies are located at lower frequency bands than the bands presented for the fourth embodiment, the quality factors of the tuning capacitors are higher, leading to lower losses and improved performance.

In addition to the benefits identified above for the first, second, and third embodiments, the fourth embodiment is capable of providing matching for variable dual-band loads at two frequencies. Both frequency bands, as well as the impedance of the load at the two frequencies, can be variable or fixed. The impedance matching at each frequency is independently of the impedance matching at the other frequency. The matching is performed with four tuning voltages, including two voltages for each frequency band.

### Fifth Embodiment

Maintaining consistent and tunable bandwidths for intermediate frequency ratios may become challenging because of the increased order of the filters and the number of associated tuning elements that may be required. In this case, an alternative embodiment, which employs band stop filters (BSFs), is now presented. For dual-band applications, this embodiment employs two rejection bands near the two frequencies. According to one implementation, the higher rejection band is located above the frequency of the higher band f₂. The lower rejection edge of this BSF is used to provide matching at f₂. Similarly, the lower rejection band is located below the frequency of the lower band f₁, and its upper edge is used to provide matching. This embodiment can be implemented using a higher rejection band below f₂ and/or a lower rejection band above f₁. It is also possible to implement this embodiment using a single rejection band and use its upper rejection edge for matching at f₂ and its lower rejection band for matching at f₁. The same phase shifters as used in the previous first-fourth embodiments can be used for this fifth embodiment.

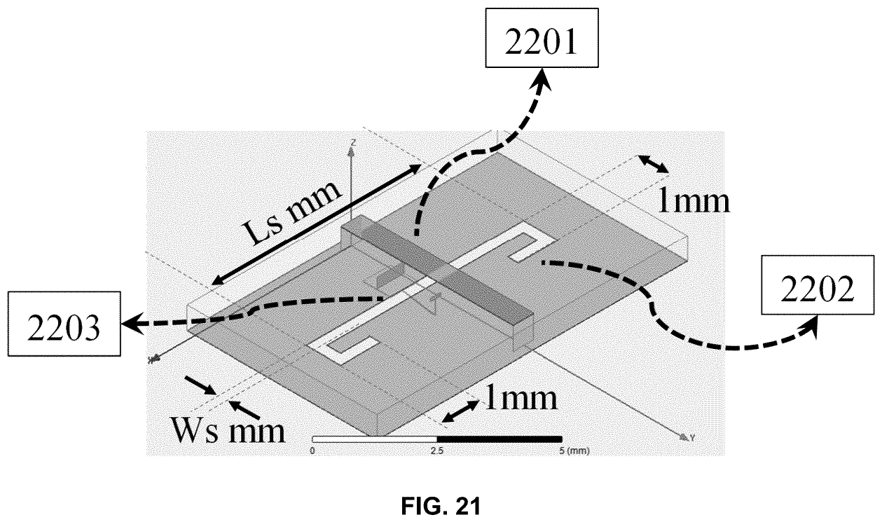

Referring now to FIG. 21, the BSFs can be implemented using 45° shunt open-circuited stubs at the expense of circuit size. Alternatively, among other methods, the BSFs can be implemented by introducing resonator slots 2202 in the ground plane of microstrip lines 2201. In this embodiment, a half-wavelength narrow slot 2202 is used on the ground plane of a microstrip line 2201 for each BSF. The slots can be folded to reduce the overall size. The BSFs can be made tunable by adding tuning elements 2203 across the slot resonators. For this purpose, the length and width of the slots are varied in accordance with the capacitance range of the tunable capacitor to achieve the desired range of output reflection coefficients.

A prototype of the fifth embodiment was designed on the same Alumina substrate used for the fourth embodiment. The prototype was intended for a dual-band load with a reflection coefficient ranging between −5 dB and −10 dB for both bands, chosen for the intention of proofing the concept. Furthermore, the concept can be applied to any fixed or variable combinations of load impedances and frequency bands. The lower and the higher matched bands were tunable over the frequency ranges of 2.5 GHz to 3.7 GHZ, and 4.5 GHz to 5.7 GHZ, respectively. The frequency ratio between these two bands varied between 1.2 (i.e. for 3.7 GHZ and 4.5 GHZ) and 2.28 (i.e. for 2.5 GHz and 5.7 GHZ). These values are used as an example to demonstrate performance for moderate frequency ratios. The concept is applicable to other frequency ratios as well.

The reflection-type phase shifters were implemented using coupled line hybrid couplers and microstrip line reflective loads. For this purpose, the reflective load comprised a series transmission line with a width and a length of 200 μm and 2,700 μm, respectively. A high-resolution switched capacitor was used with the tuning range of 0.125 pF to 5 pF to achieve wideband performance. The phase shifter could be implemented using other types of elements, such as but not limited to Lange, parallel plate, or lumped couplers. In addition, the number of tunable capacitors could be increased, as could their tuning range.

Referring to FIG. 21, both band stop filters were implemented using Ws=300 μm. The length of the slot resonator 2202, Ls, for filter 404 is 8 mm and for filter 402 is 3.5 mm.

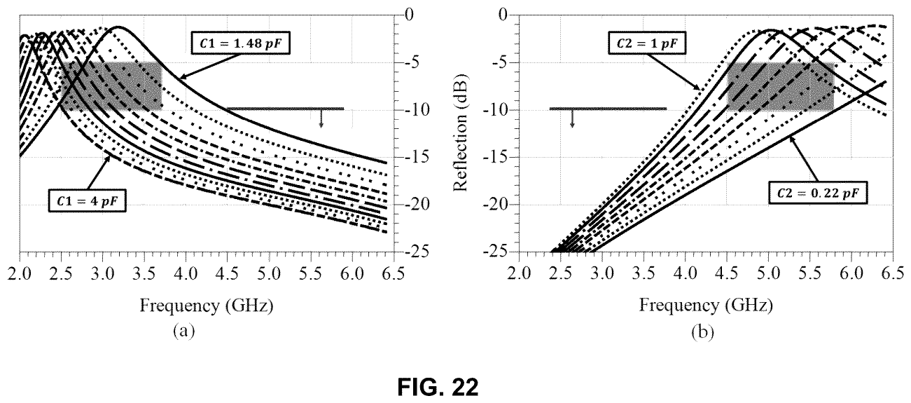

Filter 404 and filter 402 are loaded by tunable capacitors with ranges of 0.125 pF to 5 pF, and 0.22 pF to 1 pF, respectively. FIG. 22 shows the output reflection coefficient of the filter 404 and filter 402. FIG. 22(a) demonstrates that filter 404 covers the required range when the tunable capacitor is tuned from 1.48 pF to 4 pF. FIG. 22(b) demonstrates the coverage for filter 402 when the tunable capacitor is tuned from 0.22 pF to 1 pF. In both cases, the reflection coefficients remain better than −10 dB over the other band.

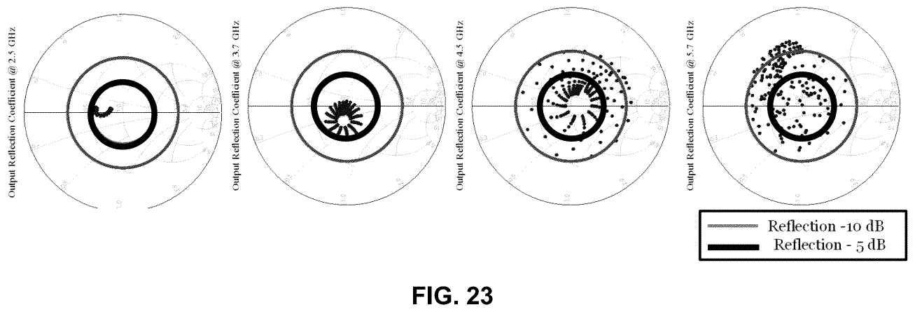

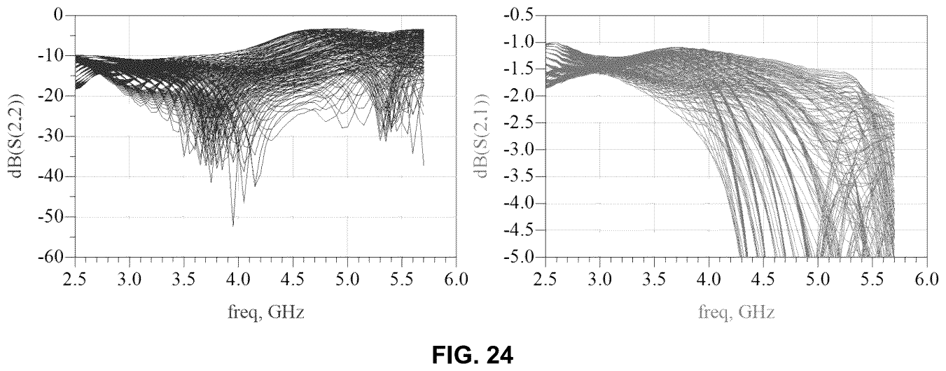

The coverage is presented at four frequency points of 2.5 GHZ, 3.7 GHZ, 4.5 GHZ, and 5.7 GHZ as the edges of the lower and higher bands. FIG. 23 shows the coverage when the tuning capacitor of filter 404 and phase shifter 403 are kept at 4 pF and 0.625 pF, respectively, and the values of the capacitors for filter 402 and phase shifter 401 are swept from 0.2 pF to 1 pF, and 0.125 pF to 5 pF, respectively. As can be seen, the output reflection coefficient of the lower band remains inside the −10 dB circle, while the reflection coefficients between the −10 dB and −5 dB circles are covered over the higher band. FIG. 24 shows the output return loss and insertion loss for the same variations in capacitor values as described above. The output return loss remains better than 10 dB and the insertion loss shows a 1 dB variation over the lower band.

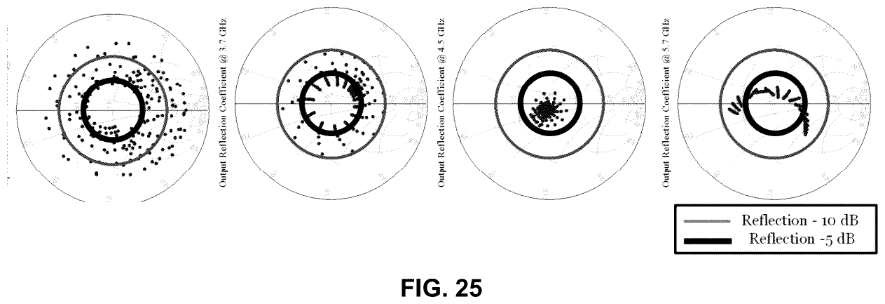

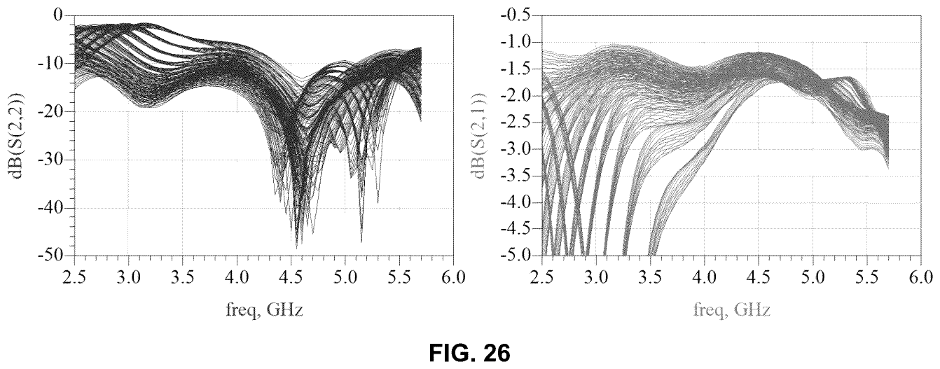

FIG. 25 shows the coverage when the capacitors of filter 402 and phase shifter 401 are set to 0.2 pF and 0.725 pF, respectively. Consistent coverage for the reflection coefficients between the −10 dB and −5 dB circles over the lower band is shown. However, the output reflection coefficient for some states extends out of the −10 dB circle at 5.7 GHZ. This is due to degraded S-parameter performance of the phase shifter at higher frequencies. This is also shown in FIG. 26, where the output return loss and insertion loss are shown for the same variations in capacitor values as described above. Here, the output reflection coefficient is worse than −10 dB beyond 5 GHZ. Moreover, the insertion loss variation is 0.8 dB over the higher band and below 5 GHZ, but reaches 3 dB near 5.7 GHZ, which indicates the poor performance of the phase shifter at these frequencies. Therefore, improved insertion loss is anticipated when this embodiment is used for low-frequency designs, high quality factor tuning capacitors are used, and/or the embodiment is fabricated using a fully integrated low-loss technology.

In addition to the benefits identified above in connection with the first, second, and third embodiments, the fifth embodiment is capable of providing matching for variable dual-band loads at two frequencies with intermediate frequency ratios. The coverage of the fifth embodiment demonstrates frequency ratios of greater than 1.2 and up to 2.2, but frequency ratios lower than 1.2 and higher than 2.2 are achievable by employing other filters and phase shifters. The use of band stop filters may reduce the need to use filters that have minimal impact on each other's matching capability. This may be applicable for cases where the frequency ratio is large enough so that the rejection bands of the band stop filters have negligible impact on each other. Consequently, frequency ratios as large as 2 may be addressed using the fifth embodiment.

There have been described various embodiments of dual-band impedance matching circuits. The proposed designs can be employed for fixed loads as well as variable loads. Moreover, the designs can address frequency-variable loads as well as changes in the frequency ratio between the two bands.

The embodiments may avoid the need to rely on modifying the characteristic impedance of any transmission line segments to provide impedance tuning at least at two frequencies.

Embodiments of the circuits may be made using current and future fabrication technologies (e.g. complementary metal-oxide-semiconductors, printed circuit board, micromachining) and tuning elements (e.g. varactors, band stop filters, micro-electromechanical systems, semiconductor switches, phase change materials, etc.).

The embodiments described herein may be modified without departing from the scope of the disclosure. For example, the circuits may be made using lumped components and distributed components at low frequencies and high frequencies, respectively.

The matching at the two frequencies enjoys a level of autonomy so that changes in load impedances can be addressed by tuning the corresponding section of the impedance tuner and not the entire network.

The embodiments may be implemented as integrated circuits with miniature sizes.

Advantages of the embodiments described herein include but are not limited to flexibility of design in terms of implementation circuit technology, compactness, the ability to address various ranges of frequency ratios, independence from high and/or low characteristic impedance of the transmission lines being used, wideband performance, ease of design, compatibility with lumped and distributed circuits, compatibility with high-power applications, compatibility with fixed and tunable load impedances, and the ability to independently match at either frequency band.

The embodiments may be used to impedance-match both frequency-variable dual-band loads as well as impedance-variable dual-band loads. The responses of the filters can be modified and/or tuned to follow the impedance variance and frequency variance of the dual-band load. This may depend on the type of filter being used (e.g. low-pass, high-pass, band-stop), the filter function (e.g. Chebyshev, maximally flat, etc.), its order (i.e. higher order filters have a sharper roll-off response near their cutoff frequency), and its cut-off edge (i.e. higher cut-off frequency or lower cut-off frequency). These degrees of freedom can be used in the design and/or tuning of each embodiment to meet the load response and its variance.

Embodiments of the disclosure may be used in various applications relating to, but not limited to, doubly-terminated matching networks (both fixed and tunable), self-interference cancelation, multiband front-end design, multiband phased array design, concurrent reconfigurable phased array design, as well as 5G and future networks. The flexibility and compatibility of the described embodiments with fabrication methods foresee a wide range of potential applications, including handheld devices as well as base stations, and satellite communication, in which circuit area, multiband performance, and power handling are valued.

Moreover, the ability of the described embodiments to be low-loss makes them desirable for high-power applications.

The word “a” or “an” when used in conjunction with the term “comprising” or “including” in the claims and/or the specification may mean “one”, but it is also consistent with the meaning of “one or more”, “at least one”, and “one or more than one” unless the content clearly dictates otherwise. Similarly, the word “another” may mean at least a second or more unless the content clearly dictates otherwise.

The terms “coupled”, “coupling” or “connected” as used herein can have several different meanings depending on the context in which these terms are used. For example, as used herein, the terms coupled, coupling, or connected can indicate that two elements or devices are directly connected to one another or connected to one another through one or more intermediate elements or devices via a mechanical element depending on the particular context. The term “and/or” herein when used in association with a list of items means any one or more of the items comprising that list.

As used herein, a reference to “about” or “approximately” a number or to being “substantially” equal to a number means being within +/−10% of that number.

While the disclosure has been described in connection with specific embodiments, it is to be understood that the disclosure is not limited to these embodiments, and that alterations, modifications, and variations of these embodiments may be carried out by the skilled person without departing from the scope of the disclosure.

It is furthermore contemplated that any part of any aspect or embodiment discussed in this specification can be implemented or combined with any part of any other aspect or embodiment discussed in this specification.

1. A dual-band impedance matching circuit, comprising:
a source having a source impedance and configured to generate an input signal at a first frequency and a second frequency;
a dual-band load having a load impedance and a first input reflection coefficient, and configured to generate, based on the input signal, an output signal at the first and second frequencies; and
a dual-band tuning component having an input connected to the source and an output connected to the load, and comprising:
at least a first filter having a first output reflection coefficient and configured, based on the first input reflection coefficient of the load, to modify at least a magnitude of the first output reflection coefficient of the first filter, and
at least a first phase shifter connected to the first filter and configured to introduce at least a first phase shift to the first output reflection coefficient of the first filter;
wherein the tuning component is configured to simultaneously match, at each of the first and second frequencies, the source impedance to the load impedance; and
wherein the tuning component is tunable so as to enable adjustment of one or more of:
the first output reflection coefficient, and
the first phase shift.

2. The circuit of claim 1, wherein the dual-band tuning component comprises:
a first tuning element comprising:
the first filter, and
the first phase shifter; and
a second tuning element comprising:
a second filter having a second output reflection coefficient and configured, based on a second input reflection coefficient of the load, to modify at least a magnitude of the second output reflection coefficient of the second filter, and
a second phase shifter connected to the second filter and configured to introduce a second phase shift to the second output reflection coefficient of the second filter.

3. The circuit of claim 2, wherein an output of the first tuning element is connected to an input of the second tuning element.

4. The circuit of claim 2, wherein the dual-band tuning component further comprises:
a first manifold structure connecting the source to each of the first tuning element and the second tuning element; and
a second manifold structure connecting each of the first tuning element and the second tuning element to the load;
wherein the first manifold structure is configured to allow the input signal to pass therethrough at the first frequency but not the second frequency; and
wherein the second manifold structure is configured to allow the input signal to pass therethrough at the second frequency but not the first frequency.

5. The circuit of claim 1, wherein:
the first frequency is lower than the second frequency; and
the first filter is a band pass filter configured, at the first frequency and the second frequency, but not at frequencies below the first frequency and at frequencies above the second frequency, to modify at least the magnitude of the first output reflection coefficient of the first filter.

6. The circuit of claim 1, wherein the first phase shifter is a dual-band phase shifter configured to introduce:
the first phase shift to the first output reflection coefficient of the first filter at the first frequency; and
a second phase shift to the first output reflection coefficient of the first filter at the second frequency.

7. The circuit of claim 2, wherein:
the first frequency is lower than the second frequency;
the first phase shifter is configured to introduce the first phase shift to the first output reflection coefficient of the first filter at the first frequency, wherein the first phase shift is up to 180°; and
the second phase shifter is configured to introduce the second phase shift to the second output reflection coefficient of the second filter at the second frequency, wherein the second phase shift is up to 180°.

8. The circuit of claim 2, wherein:
the first frequency is lower than the second frequency;
the first filter is one of:
a low-pass filter configured, at the first frequency but not the second frequency, to modify at least the magnitude of the output reflection coefficient of the low-pass filter, and
a high-pass filter configured, at the second frequency but not the first frequency, to modify at least the magnitude of the output reflection coefficient of the high-pass filter; and
the second filter is the other of:
the low-pass filter, and
the high-pass filter.

9. The circuit of claim 2, wherein at least one of the first phase shifter and the second phase shifter comprises a transmission line segment.

10. The circuit of claim 1, wherein the first phase shifter is a reflection-type phase shifter comprising a 90° coupler connected to a pair of reflective loads.

11. The circuit of claim 1, wherein the first phase shifter comprises a dual-band branch-line coupler comprising a pair of T-networks or pi-networks.

12. The circuit of claim 2, wherein:
one or more of the first filter, the first phase shifter, the second filter, and the second phase shifter is tunable so as to enable adjustment of, respectively, one or more of the first output reflection coefficient, the first phase shift, the second output reflection coefficient, and the second phase shift.

13. The circuit of claim 2, wherein:
each of the first phase shifter and the second phase shifter is a reflection-type phase shifter comprising a 90° coupler connected to a reflective load; and
each of the first phase shifter and the second phase shifter is tunable so as to enable adjustment of, respectively, the first phase shift and the second phase shift.

14. The circuit of claim 1, wherein the first filter is a band stop filter configured, at the first frequency and the second frequency, but not at frequencies between the first frequency and the second frequency, to modify at least the magnitude of the first output reflection coefficient of the first filter.

15. The circuit of claim 14, wherein the band stop filter comprises one or more of:
one or more open-circuited stubs; and
one or more slots in a ground plane of one or more microstrip lines.

16. The circuit of claim 1, wherein the tuning component comprises one or more lumped or distributed circuit components.

17. A dual-band impedance matching circuit, comprising:
a source having a source impedance and configured to generate an input signal at a first frequency and a second frequency;
a dual-band load having a load impedance and first and second input reflection coefficients, and configured to generate, based on the input signal, an output signal at the first and second frequencies;
a first tuning element comprising:
a first filter having a first output reflection coefficient and configured, based on the first input reflection coefficient of the load, to modify at least a magnitude of the first output reflection coefficient of the first filter, and
a first phase shifter connected to the first filter and configured to introduce a first phase shift to the first output reflection coefficient of the first filter; and
a second tuning element comprising:
a second filter having a second output reflection coefficient and configured, based on the second input reflection coefficient of the load, to modify at least a magnitude of the second output reflection coefficient of the second filter, and
a second phase shifter connected to the second filter and configured to introduce a second phase shift to the second output reflection coefficient of the second filter;
wherein the tuning component is configured to simultaneously match, at each of the first and second frequencies, the source impedance to the load impedance; and
wherein:
the first frequency is lower than the second frequency,
the first filter is one of:
a low-pass filter configured to allow the input signal to pass therethrough at the first frequency but not the second frequency, and
a high-pass filter configured to allow the input signal to pass therethrough at the second frequency but not the first frequency, and
the second filter is the other of:
the low-pass filter, and
the high-pass filter.

18. A dual-band impedance matching circuit, comprising:
a source having a source impedance and configured to generate an input signal at a first frequency and a second frequency, wherein the first frequency is lower than the second frequency;
a dual-band load having a load impedance and a first input reflection coefficient, and configured to generate, based on the input signal, an output signal at the first and second frequencies; and
a dual-band tuning component having an input connected to the source and an output connected to the load, and comprising:
a band pass filter having an output reflection coefficient and configured, at the first frequency and the second frequency, but not at frequencies below the first frequency and at frequencies above the second frequency, to modify, based on the input reflection coefficient of the load, a least a magnitude of the output reflection coefficient of the band pass filter, and
a dual-band phase shifter connected to the filter and configured to introduce, at the first frequency, a first phase shift to the output reflection coefficient of the band pass filter and, at the second frequency, a second phase shift to the output reflection coefficient of the band pass filter;
wherein the tuning component is configured to simultaneously match, at each of the first and second frequencies, the source impedance to the load impedance.
